(19) United States
(12) Patent Application Publication
(10) Pub. No.: US 2012/0150478 A1
(43) Pub. Date: Jun. 14, 2012

(54) METHOD OF TESTING AN OBJECT AND APPARATUS FOR PERFORMING THE SAME

(76) Inventors: Ki-Jae Song, Paju-si (KR); Sung-Soo Lee, Asan-si (KR)

(21) Appl. No.: 13/325,154

(22) Filed: Dec. 14, 2011

(30) Foreign Application Priority Data
Dec. 14, 2010 (KR) 10-2010-0127368

(51) Int. Cl. G06F 19/00; H01L 21/66; G01R 31/26

(52) U.S. Cl. 702/120; 702/123; 438/15; 257/E21.53

(57) ABSTRACT

In a method of testing an object, a first test pattern for testing a first device in the object may be set in a tester. A second test pattern for testing a second device in the object may be set in a test head electrically connected between the tester and the object. The first test pattern may be provided to the first device through the test head and the second test pattern may be provided to the second device by the test head to simultaneously test the first device and the second device. Thus, the first device and the second device different from each other may be simultaneously tested without changing test conditions in the tester, so that a time for testing the object may be reduced.

### CROSS-RELATED APPLICATION

This application claims priority under 35 USC §119 to Korean Patent Application No. 2010-0127368, filed on Dec. 14, 2010 in the Korean Intellectual Property Office (KIPO), the contents of which are herein incorporated by reference in their entirety.

### BACKGROUND

Example embodiments relate to a method of testing an object and an apparatus for performing the same. More particularly, example embodiments relate to a method of testing electrical characteristics of a multi-chip package including sequentially stacked semiconductor chips, an apparatus for performing the method, and a method of manufacturing a semiconductor chip using the apparatus.

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

Further, in order to provide a semiconductor package with various functions, a multi-chip package including stacked semiconductor chips that may have different functions may be developed.

Electrical characteristics of the multi-chip package may be tested using a test apparatus. The test apparatus may include a tester and a test head. Test conditions may be set in the tester. Here, because the multi-chip package may include different semiconductor chips, a plurality of test conditions may be set in the tester. The test head may make contact with external terminals of the multi-chip package. The test conditions in the tester may be provided to the multi-chip package through the test head.

However, because the test conditions may be different from each other in accordance with characteristics of the semiconductor chips, the different semiconductor chips may not be simultaneously tested. Thus, after a first semiconductor chip is tested using a first test condition in the tester, a second test condition may be set in the tester. A second semiconductor chip may then be tested using the second test condition. This may require a long time for testing the multi-chip package.

### SUMMARY

Example embodiments provide a method of simultaneously testing different devices in an object.

Example embodiments also provide an apparatus for performing the above-mentioned method.

Additional example embodiments provide a method of manufacturing a semiconductor package using the above-mentioned method and apparatus.

In one embodiment, a method of testing an object is disclosed. The method includes: setting a first test pattern by a tester, the first test pattern used for testing a first device in the object; setting a second test pattern by a test head that is electrically connected between the tester and the object, the second test pattern used for testing a second device different from the first device in the object; and applying the first test pattern to the first device through the test head and the second test pattern to the second device by the test head to simultaneously test the first device and the second device.

In another embodiment, an apparatus for testing an object is disclosed. The apparatus includes a tester for testing a first device in the object. The tester is configured to generate a first algorithmic pattern for testing the first device and apply the first algorithmic pattern to the first device. The apparatus further includes a test head electrically connected between the tester and the object to test a second device of the object different from the first device. The test head is configured to generate a second algorithmic pattern different from the first algorithmic pattern, and to apply the second algorithmic pattern to the second device. The tester is configured to apply the first algorithmic pattern to the first device through the test head.

In a further embodiment, a method of manufacturing a semiconductor package is disclosed. The method includes: stacking a first chip having a first type on a second chip having a second type different from the first type; receiving, by the first chip, a first test pattern generated at a tester; receiving, by the second chip, a second test pattern different from the first test pattern and generated at a test head connected to the tester; and testing the first chip using the received first test pattern at the same time as testing the second chip using the received second test pattern.

### BRIEF DESCRIPTION OF THE DRAWINGS

Example embodiments will be more clearly understood from the following detailed description taken in conjunction with the accompanying drawings. FIGS. 1 to 6 represent non-limiting, example embodiments as described herein.

FIG. 1 is a block diagram illustrating an apparatus for testing an object in accordance with some example embodiments;

FIG. 2 is a flow chart illustrating a method of testing an object using the apparatus in FIG. 1, according to an exemplary embodiment;

FIG. 3 is a block diagram illustrating an apparatus for testing an object in accordance with some example embodiments;

FIG. 4 is a flow chart illustrating a method of testing an object using the apparatus in FIG. 3, according to an exemplary embodiment;

FIG. 5 is a diagram illustrating an apparatus for testing an object in accordance with some example embodiments; and

FIG. 6 is a flow chart illustrating a method of manufacturing a semiconductor package, according to an exemplary embodiment.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. Unless indicated otherwise, these terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

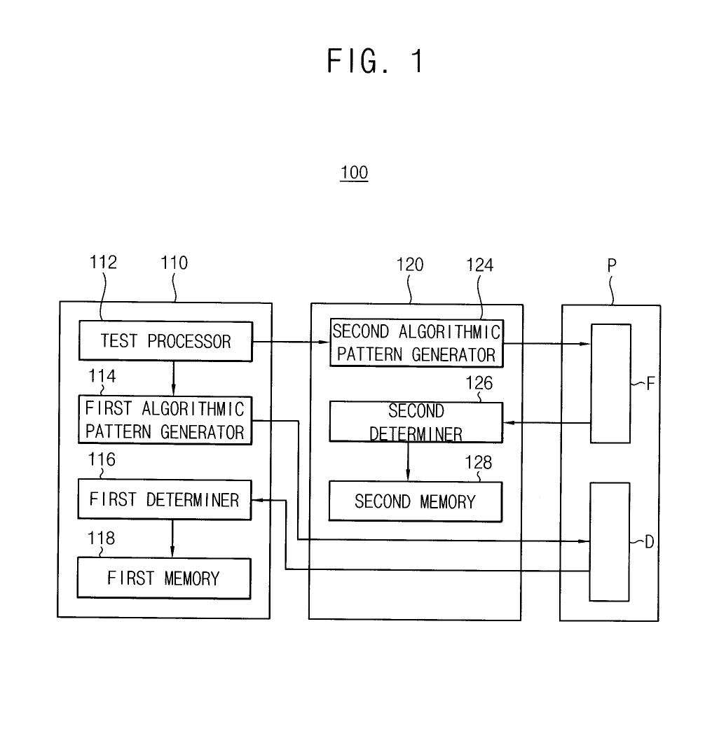

FIG. 1 is a block diagram illustrating an apparatus for testing an object in accordance with some example embodiments.

Referring to FIG. 1, an apparatus 100 for testing an object P in accordance with this example embodiment may include a tester 110 and a test head 120. In some example embodiments, the test apparatus 100 may simultaneously test a first device and a second device in the object P different from each other. The first device and second device may be, for example, semiconductor chips of a different type. The object P may include, for example, a multi-chip package. In one embodiment, the multi-chip package P includes a first semiconductor chip D and a second semiconductor chip F. The first semiconductor chip D may include, for example, a DRAM device. The second semiconductor chip F may include, for example, a flash memory device. However, other types of semiconductor chips may be used, and more than two semiconductor chips may be used.

The tester 110 may test electrical characteristics of the first semiconductor chip D, and may also test electrical characteristics of the second semiconductor chip F. For example, each of semiconductor chips D and F may be tested under first test conditions (e.g., depending on variables such as temperature, humidity, applied electric field, etc.), and each of semiconductor chips D and F may also be tested under second, third, etc., test conditions. In addition, for each test condition, each semiconductor chip may have a particular test pattern (i.e., group or series of signals, having particular voltages) applied to its circuitry in order to test the chip. For example, for each test condition, a first test pattern for testing the electrical characteristics of the first semiconductor chip D may be set in the tester 110, a second test pattern for testing the second semiconductor chip F may be set in the tester 110, etc. The test patterns may be different so that the different chips are tested separately. As a result, an indication of a failure of one of the chips does not necessarily indicate a failure of the entire package.

In some example embodiments, the tester 110 may be a test device that includes input and output interfaces (e.g., dials, buttons, switches, a screen, audio output, etc.), a test processor 112, a first algorithmic pattern generator 114, a first determiner 116 and a first memory 118. For example, each of test processor 112, first algorithmic pattern generator 114, first determiner 116, and first memory 118 may include modules including processing circuitry, logic, and/or storage elements for implementing their functionality.

In one embodiment, the test processor 112 controls test operations of the tester 110 and the test head 120. Thus, control signals generated from the test processor 112 may be used by the tester 110 and inputted to the test head 120.

The first algorithmic pattern generator 114 may receive the control signals from the test processor 112 to generate a first algorithmic pattern for testing the first semiconductor chip D. Because the first semiconductor chip D may include the DRAM device, the first algorithmic pattern may have a waveform corresponding to the DRAM device. The first algorithmic pattern may be transmitted to the first semiconductor chip D through the test head 120. For example, in one embodiment, the test head includes a first set of electrical connections (i.e., wires, pins, etc.) that directly connect the tester to the object (e.g., a semiconductor package) that includes the first semiconductor chip D without the use of any intermediary processing circuitry in the test head. The first set of electrical connections may connect, for example, the tester to input/output terminals on a package substrate of the package that includes the first semiconductor chip D. In one embodiment, those terminals may be dedicated to the first semiconductor chip D, and separate terminals on the package substrate may be dedicated to a second semiconductor chip.

The first determiner 116 may receive and analyze signals outputted from the first semiconductor chip D to which the first algorithmic pattern is applied to determine whether the first semiconductor chip D may be normal or not (e.g., whether it operates properly within specification parameters or not). Thus, the signals outputted from the first semiconductor chip D may be received in the first determiner 116.

The first memory 118 may store information from the first determiner 116. For example, when a portion of the first semiconductor chip D may be determined to be abnormal or not functioning properly, by the first determiner 116, position information of the abnormal portion in the first semiconductor chip D may be stored in the first memory 118. The first memory 118 may be communicatively connected to additional processing circuitry in tester 110, or may include functionality that permits a user or machine to access the test results (i.e., by displaying results on a screen, storing the results to a removable memory that can be used in other equipment to review the results, sending instructions to equipment based on test results to cause the machine to remove failed chips or packages, etc.).

In some example embodiments, other algorithmic patterns as well as the first algorithmic pattern may be generated from the first algorithmic pattern generator 114. Thus, various semiconductor chips may be tested with different algorithmic patterns using only the tester 110.

In one embodiment, in order to simultaneously test the first semiconductor chip D and the second semiconductor chip F, the test head 120 may test the second semiconductor chip F. For example, the test head 120 may be electrically connected to the tester 110 to receive the control signals from the test processor 112. Further, the test head 120 may electrically make contact with external terminals of the multi-chip package P. In some example embodiments, a first test pattern may be applied to first external terminals connected with the first semiconductor chip D among the entire external terminals. In addition, the second test pattern may be applied to external terminals connected with the second semiconductor chip F. Thus, the first test pattern and the second test pattern may be simultaneously applied to different chips of the multi-chip package P, so that the first semiconductor chip D and the second semiconductor chip F can be simultaneously tested.

In some example embodiments, the test head 120 may include a second algorithmic pattern generator 124, a second determiner 126 and/or a second memory 128. Each of second algorithmic pattern generator 124, second determiner 126, and second memory 128 may include modules including processing circuitry, logic, and/or storage elements for implementing their functionality.

In one embodiment, the second algorithmic pattern generator 124 receives the control signals from the test processor 112 to generate a second algorithmic pattern for testing the second semiconductor chip F. Because the second semiconductor chip F may include the flash memory device, the second algorithmic pattern may have a waveform corresponding to the flash memory device that is different from the waveform of the first algorithmic pattern discussed previously.

The second determiner 126 may analyze signals outputted from the second semiconductor chip F to which the second algorithmic pattern may be applied to determine whether the second semiconductor chip F may be normal or not (e.g., whether it operates properly within specification parameters or not). Thus, the signals outputted from the second semiconductor chip F may be received in the second determiner 126.

The second memory 128 may store information from the second determiner 126. For example, when a portion of the second semiconductor chip F may be determined to be abnormal by the second determiner 126, position information of the abnormal portion in the second semiconductor chip F may be stored in the second memory 128. Though not shown, second memory 128 may be a removable memory, or may be connected to tester 110 or other equipment, so that the information it stores can be analyzed, reviewed, and/or used.

Additionally, when the multi-chip package P further includes additional semiconductor chips, such as a third semiconductor chip, the additional semiconductor chips may also be tested with the apparatus 100. For example, if the third semiconductor chip is substantially the same as the second semiconductor chip F, the third semiconductor chip may be tested using the test head 120. Because the test head 120 may be operated by receiving the control signals from the test processor 112, the third semiconductor chip may be tested after testing the first semiconductor chip D and second semiconductor chip F.

Although the test processor 112, first algorithmic pattern generator 114, first determiner 116, and first memory 118 are shown separately in FIG. 1, some or all of them may be combined into a shared module. Similarly, although second algorithmic pattern generator 124, second determiner 126, and second memory 128 are shown separately, some or all of them may be combined into a shared module. In addition, some of the modules, such as second determiner 126 and/or second memory 128 shown in FIG. 1 may be included in the tester 110 rather than the test head 120, so long as the first and second test patterns can be separately generated and analyzed to allow for simultaneous testing of the different semiconductor chips.

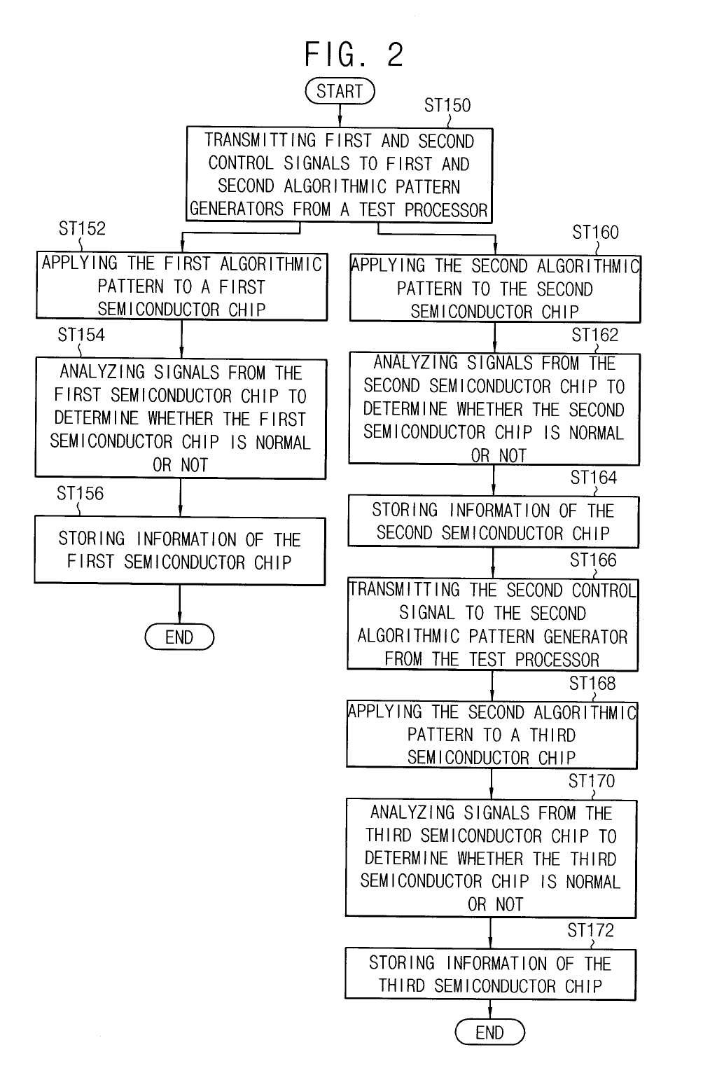

FIG. 2 is a flow chart illustrating an exemplary method of testing an object using the apparatus in FIG. 1.

Referring to FIGS. 1 and 2, in step ST 150, the test processor 112 transmits a first control signal to the first algorithmic pattern generator 114. Further, the test processor 112 transmits a second control signal to the second algorithmic pattern generator 124. In some example embodiments, the first control signal and the second control signal are transmitted simultaneously with each other.

In step ST 152, the first algorithmic pattern generator 114 generates the first algorithmic pattern in accordance with the first control signal. The first algorithmic pattern may be inputted into the first semiconductor chip D through the test head 120.

Further, in step ST160, the second algorithmic pattern generator 124 generates the second algorithmic pattern in accordance with the second control signal. The second algorithmic pattern may be inputted into the second semiconductor chip F. In some example embodiments, the first algorithmic pattern and the second algorithmic pattern are inputted simultaneously with each other to the respective first and second semiconductor chips.

In step ST154, signals are outputted from the first semiconductor chip D to which the first algorithmic pattern is applied. The first determiner 116 may receive the signals from the first semiconductor chip D. The first determiner 116 analyzes the signals from the first semiconductor chip D to determine whether the first semiconductor chip D is normal or not.

Further, in step ST162, signals are outputted from the second semiconductor chip F to which the second algorithmic pattern is applied. The second determiner 126 may receive the signals from the second semiconductor chip F. The second determiner 126 may analyze the signals from the second semiconductor chip F to determine whether the second semiconductor chip F is normal or not. In some example embodiments, determining whether the first semiconductor chip D and the second semiconductor chip F are normal or not may be performed simultaneously with each other.

In step ST156, information of the first semiconductor chip D from the first determiner 116 is stored in the first memory 118.

Further, in step ST164, information of the second semiconductor chip F from the second determiner 126 is stored in the second memory 128.

In one embodiment, each of steps ST152, ST154, and ST156 occur simultaneously with respective corresponding steps ST160, ST162, and ST164. However, such functionality is not required. In certain embodiments, at least part, but not necessarily all, of the combined steps ST152, ST154, and ST156 overlaps with at least part, but not necessarily all, of the combined steps ST160, ST162, and ST164. As a result, testing of the first chip occurs simultaneously with testing of the second chip.

In one embodiment, after the second semiconductor chip F is tested, in step ST166, the test processor 112 may transmit a third control signal to the second pattern algorithmic generator 124. The third control signal may be the same control signal as the second control signal previously applied to the second pattern algorithmic generator 124. For example, if there are two or more chips of the same type as the second chip F, a subsequent control signal (i.e., the third control signal) may be sent to the test head 120 to instruct the test head 120 to test an additional chip.

In step ST168, the second algorithmic pattern generator 124 generates a third algorithmic pattern in accordance with the third control signal. The third algorithmic pattern may be the same as the second algorithmic pattern generated previously by the second pattern algorithmic generator 124. The third algorithmic pattern may be inputted into a third semiconductor chip.

In step ST170, signals are outputted from the third semiconductor chip to which the third algorithmic pattern was applied. The second determiner 126 receives the signals from the third semiconductor chip. The second determiner 126 may analyze the signals from the third semiconductor chip to determine whether the third semiconductor chip is normal or not.

Further, in step ST172, information of the third semiconductor chip from the second determiner 126 may be stored in the second memory 128.

Although not described in the examples above, in one embodiment, the information stored in the second memory 128 is transmitted to the tester 110 or to another device or equipment, so that it can be analyzed, reviewed, and/or used in a further process.

According to this example embodiment, the first semiconductor chip in the multi-chip package may be tested using the tester and the second semiconductor chip in the multi-chip package may be tested using the test head. Thus, the first semiconductor chip and the second semiconductor chip may be simultaneously tested without change of the tester (e.g., without needing to re-program the tester to produce the second algorithmic pattern), so that a time for testing the multi-chip package may be remarkably reduced.

The embodiments described above may be used to more easily and more quickly test two different chips in a package that use two different test patterns. For example, both chips can be tested at the same time for the same test conditions (e.g., for the same temperature and humidity), instead of one chip being tested first, and the second chip being subsequently tested second.

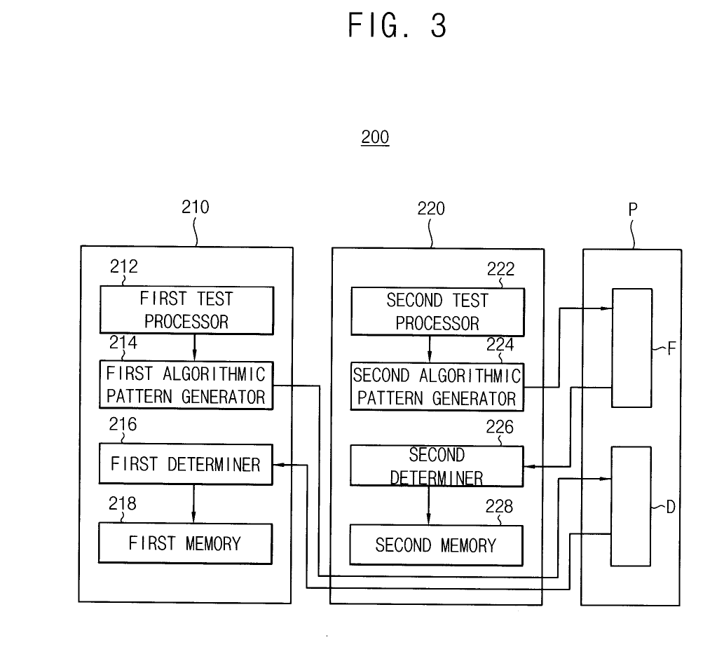

FIG. 3 is a block diagram illustrating an apparatus for testing an object in accordance with some example embodiments.

Referring to FIG. 3, an apparatus 200 for testing an object P in accordance with this example embodiment may include a tester 210 and a test head 220. In some example embodiments, the object P may include a multi-chip package having a first semiconductor chip D and a second semiconductor chip F different from each other.

The tester 210 may test electrical characteristics of the first semiconductor chip D. Thus, a first test pattern for testing the electrical characteristics of the first semiconductor chip D may be set in the tester 210.

In some example embodiments, the tester 210 may include a first test processor 212, a first algorithmic pattern generator 214, a first determiner 216 and a first memory 218.

The first test processor 212 may control test operations of the tester 210. Thus, first control signals generated from the first test processor 212 may be inputted into the first algorithmic pattern generator 214.

In some example embodiments, the first algorithmic pattern generator 214, the first determiner 216 and the first memory 218 may be substantially the same as the first algorithmic pattern generator 114, the first determiner 116 and the first memory 118, respectively. Therefore, any further illustrations with respect to the first algorithmic pattern generator 214, the first determiner 216 and the first memory 218 may be omitted herein for brevity.

In some example embodiments, the test head 220 may not be electrically connected with the first test processor 212. Thus, the first control signal from the first test processor 212 may not be transmitted to the test head 220. The test head 220 may electrically make contact with the external terminals of the multi-chip package P.

In some example embodiments, the test head 220 may include a second test processor 222, a second algorithmic pattern generator 224, a second determiner 226 and a second memory 228.

The second test processor 222 may control test operations of the test head 220. Thus, second control signals generated from the second test processor 222 may be inputted into the second algorithmic pattern generator 224.

In some example embodiments, the second algorithmic pattern generator 224, the second determiner 226 and the second memory 228 may be substantially the same as the second algorithmic pattern generator 124, the second determiner 126 and the second memory 128, respectively. Therefore, any further illustrations with respect to the second algorithmic pattern generator 224, the second determiner 226 and the second memory 228 may be omitted herein for brevity.

In some example embodiments, the test head 220 may include the second test processor 222. Thus, the test head 220 may control testing of the second semiconductor chip F independent of the operations of the first test processor 212 in the tester 210. Therefore, before completing the test of the first semiconductor chip D by the tester 210, the third semiconductor chip substantially the same as the second semiconductor chip F may be tested using a control signal from the test head 220 independently received from the second test processor 222. As a result, the first semiconductor chip D and the third semiconductor chip may be simultaneously tested.

Though not shown, part of the test head circuitry (e.g., the memory) may be connected to the tester 210, so that the tester 210 may present a resulting analysis of both semiconductor chips D and F. Alternatively, the test head may include removable memory that can be inserted into an external system to transmit the test information of the second semiconductor chip to be analyzed, may include an output interface to indicate which chips have failed and which are operating properly, or may connect to automated equipment that performs a further process, such as controlling which chips or packages are removed as failed chips or packages.

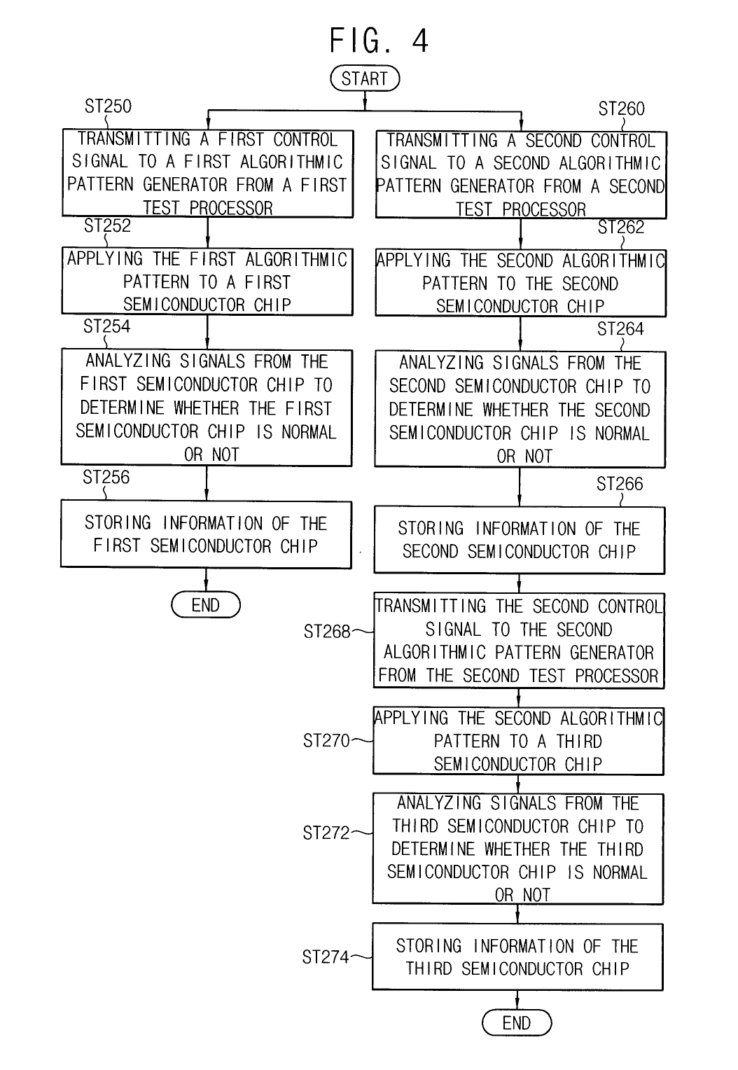

FIG. 4 is an exemplary flow chart illustrating a method of testing an object using the apparatus in FIG. 3.

Referring to FIGS. 3 and 4, in step ST 250, the first test processor 212 transmits the first control signal to the first algorithmic pattern generator 214.

Further, in step ST260, the second test processor 222 transmits the second control signal to the second algorithmic pattern generator 224. In some example embodiments, the first control signal and the second control signal may be transmitted simultaneously with each other.

In step ST 252, the first algorithmic pattern generator 214 generates the first algorithmic pattern in accordance with the first control signal. The first algorithmic pattern may be inputted into the first semiconductor chip D through the test head 220.

Further, in step ST262, the second algorithmic pattern generator 224 generates the second algorithmic pattern in accordance with the second control signal. The second algorithmic pattern may be inputted into the second semiconductor chip F. In some example embodiments, the first algorithmic pattern and the second algorithmic pattern may be inputted simultaneously with each other.

In step ST254, signals are be outputted from the first semiconductor chip D to which the first algorithmic pattern is applied. The first determiner 216 receives the signals from the first semiconductor chip D. The first determiner 216 may analyze the signals from the first semiconductor chip D to determine whether the first semiconductor chip D is normal or not.

Further, in step ST264, signals are outputted from the second semiconductor chip F to which the second algorithmic pattern is applied. The second determiner 226 receives the signals from the second semiconductor chip F. The second determiner 226 may analyze the signals from the second semiconductor chip F to determine whether the second semiconductor chip F is normal or not. In some example embodiments, determining whether the first semiconductor chip D and the second semiconductor chip F is performed simultaneously with each other.

In step ST256, information of the first semiconductor chip D from the first determiner 216 may be stored in the first memory 218.

Further, in step ST266, information of the second semiconductor chip F from the second determiner 226 may be stored in the second memory 228.

Before the testing of first semiconductor chip D is complete, in step ST268, the second test processor 222 may transmit the second control signal to the second pattern algorithmic generator 224.

In step ST270, the second algorithmic pattern generator 224 may generate the second algorithmic pattern in accordance with the second control signal. The second algorithmic pattern may be inputted into the third semiconductor chip.

In step ST272, signals may be outputted from the third semiconductor chip to which the second algorithmic pattern may be applied. The second determiner 226 may receive the signals from the third semiconductor chip. The second determiner 226 may analyze the signals from the third semiconductor chip to determine whether the third semiconductor chip is normal or not. As a result, according to the embodiments described herein, different groups of semiconductor chips in an individual package or object may be tested simultaneously, while the individual chips within the groups are tested sequentially. In addition, the different groups can be tested simultaneously, with certain chips within each group being also tested simultaneously. For example, a package that includes a first chip of a first type (e.g., a DRAM chip) and a plurality of identically structured second chips of a second type (e.g., flash memory chips) may test the first chip and all of the second chips simultaneously.

In step ST274, information of the third semiconductor chip from the second determiner 226 may be stored in the second memory 228.

According to this example embodiment, the test head may include the second test processor. Thus, the third semiconductor chip may be tested during testing the first semiconductor chip. As a result, a waiting time for testing the third semiconductor chip substantially the same as the second semiconductor chip may be unnecessary, so that the time for testing the multi-chip package may be more reduced.

In some example embodiments, the object may include the multi-chip package. Alternatively, other objects including different devices (e.g., semiconductor modules including a plurality of chips or packages) may be tested using the apparatus of example embodiments.

According to some example embodiments, the first device in the object may be tested using the tester. The second device in the object may be tested using, either entirely, or in part, the test head. Thus, the first device and the second device different from each other may be simultaneously tested without changing test conditions in the tester, so that a time for testing the object is remarkably reduced.

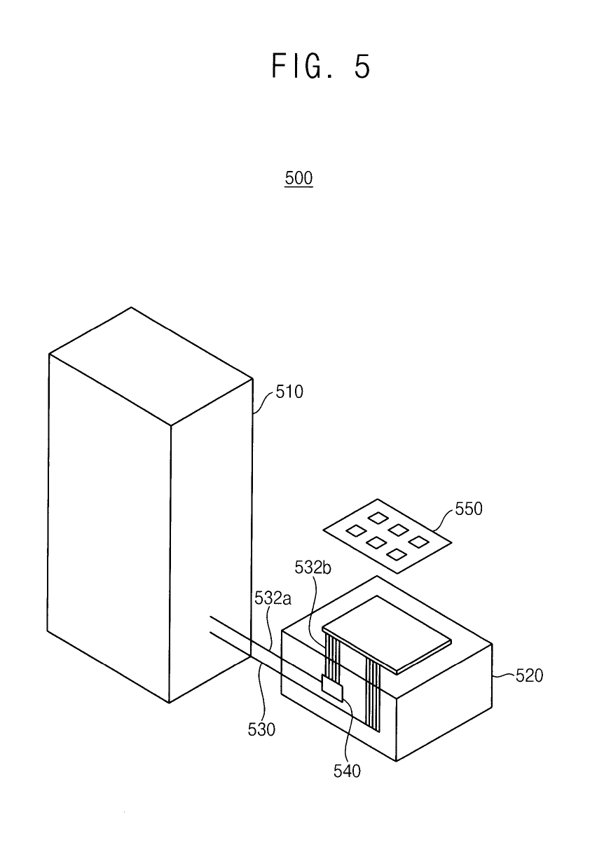

FIG. 5 is a diagram illustrating an apparatus 500 for testing an object in accordance with some example embodiments. As shown in FIG. 5, the apparatus 500 includes a tester 510 and a test head 520. The tester 510 and test head 520 may be separate devices spaced apart from each other, and in one embodiment, are connected by wires. The tester 510 may include test equipment including known components, and the test head 520 may include known test head components. For example, the test head 520 may include a set of wires 530 that connect to probes (not shown) to form a set of electrical connections that directly electrically connect the tester 510 to an object 550 being tested. In addition, the test head 520 may include additional electrical connections, such as a set of wires 532a and 532b, and probes (not shown) that indirectly electrically connect the tester 510 to the object 550 being tested, through circuitry 540. Circuitry 540 may include, for example, various logic, processing, and/or memory circuitry that permits test head 520 to perform at least part of a testing procedure, so that tester 510 and test head 520 can simultaneously perform testing of two different devices (e.g., semiconductor chips) of object 550, in a manner such as described in the above embodiments.

Although certain elements are shown in FIG. 5, these elements are exemplary only, and need not be used to implement the apparatus and methods described above. For example, wires 532a (which may include one or more wires) may be omitted in certain embodiments, and the devices depicted in object 550 need not be arranged in the manner shown, and may include, for example, one or more semiconductor packages, such as described above. In addition, though the test head 520 is depicted as being stationary, while the object 550 is shown as moveable, the test head 520 may also be moveable, and may be connected to the tester, for example, using a flexible wire or other adjustable connection mechanism.

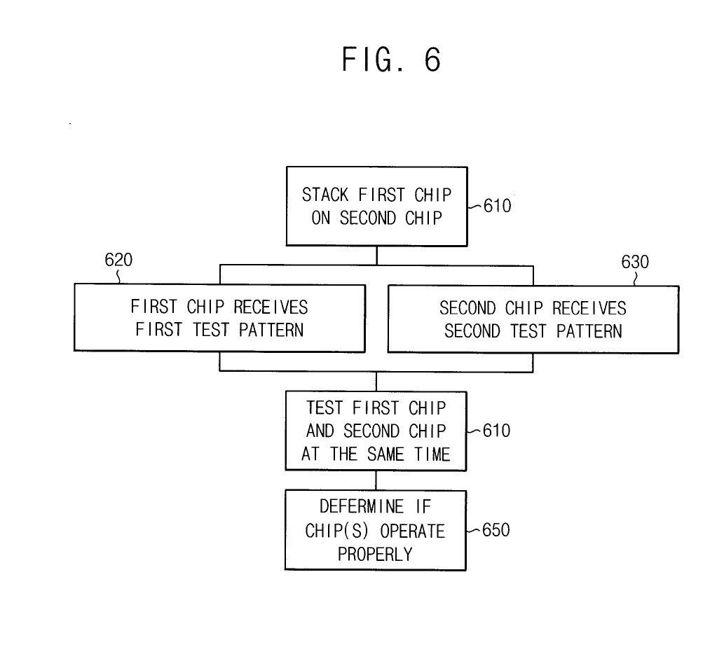

FIG. 6 is a flow chart illustrating a method 600 of manufacturing a semiconductor package, according to an exemplary embodiment. In step 610, a first chip is stacked on a second chip. For example, the two chips may be part of a semiconductor package. The first chip may have a first type and the second chip may have a second type different from the first type. For example, the first chip may be a DRAM chip, and the second chip may be a flash memory chip. However, the chips need not be memory chips, and one or more of them may be, for example, logic chips or include logic functionality. In one embodiment, the chips may be further stacked on a package substrate to form a package.

In step 620, the first chip receives a first test pattern generated at a tester. The test pattern may be, for example, a first algorithmic pattern generated at the tester. In step 630, the second chip receives a second test pattern different from the first test pattern and generated at a test head connected to the tester. For example, the second test pattern may be a second algorithmic pattern generated at the test head. In one embodiment, steps 620 and 630 may occur at the same time.

In step 640, the first chip is tested using the received first test pattern at the same time that the second chip is tested using the received second test pattern. For example, at least part of the testing of the first chip and the second chip may overlap and occur simultaneously, or substantially all of the testing of the first chip and the second chip may overlap and occur simultaneously.

In step 650, based on the testing of the first chip and the testing of the second chip, it is determined whether at least one of the first chip and the second chip are operating properly. Then, further processing (not shown) may be performed on the tested chips (e.g., removing the chips as failed chips), based on the determination.

The foregoing is illustrative of example embodiments and is not to be construed as limiting thereof Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of testing an object, the method comprising:
setting a first test pattern by a tester, the first test pattern used for testing a first device in the object;
setting a second test pattern by a test head that is electrically connected between the tester and the object, the second test pattern used for testing a second device different from the first device in the object; and
applying the first test pattern to the first device through the test head and the second test pattern to the second device by the test head to simultaneously test the first device and the second device.

2. The method of claim 1, wherein setting the first test pattern by the tester comprises generating a first algorithmic pattern corresponding to the first device, and setting the second test pattern by the test head comprises generating a second algorithmic pattern corresponding to the second device, the second algorithmic pattern being different from the first algorithmic pattern.

3. The method of claim 1, wherein simultaneously testing the first device and the second device comprises analyzing signals outputted from the first device and the second device to determine whether the first device and the second device operate properly.

4. The method of claim 1, wherein the first device comprises a first semiconductor chip, the second device comprises a second semiconductor chip, and the object comprises a multi-chip package having the first semiconductor chip and the second semiconductor chip sequentially stacked.

5. The method of claim 4, wherein the first device comprises a first type of memory chip, and the second device further comprises a second type of memory chip, the first type being different from the second type.

6. The method of claim 5, wherein the first type of memory chip is a DRAM chip, and the second type of memory chip is a flash memory chip.

7. The method of claim 5, wherein the multi-chip package further comprises a third device, the third device comprising a memory chip having the second type, and further comprising:
after testing the second device, testing the third device by applying the second condition to the third device.

8. An apparatus for testing an object, the apparatus comprising:
a tester for testing a first device in the object, the tester configured to generate a first algorithmic pattern for testing the first device and apply the first algorithmic pattern to the first device; and
a test head electrically connected between the tester and the object to test a second device of the object different from the first device, the test head configured to generate a second algorithmic pattern different from the first algorithmic pattern, and to apply the second algorithmic pattern to the second device,
wherein the tester is configured to apply the first algorithmic pattern to the first device through the test head.

9. The apparatus of claim 8, wherein:
the apparatus is configured to apply the first algorithmic pattern to the first device at the same time that it applies the second algorithmic pattern to the second device.

10. The apparatus of claim 9, wherein:
the object is a multi-chip package, the first device is a first chip having a first type, and the second device is a second device having a second type different from the first type, wherein the apparatus is configured to test the first chip using the first algorithmic pattern at the same time that it tests the second chip using the second algorithmic pattern.

11. The apparatus of claim 10, wherein:
the multi-chip package includes a package substrate, wherein:
the apparatus is configured to apply both the first algorithmic pattern to the first chip and the second algorithmic pattern to the second chip through the package substrate.

12. The apparatus of claim 8, wherein the tester comprises a test processor for controlling test operations of the first device and the second device.

13. The apparatus of claim 12, wherein the tester is configured to generate the first algorithmic pattern based on a control signal from the test processor, and the test head is configured to generate the second algorithmic control pattern based on a control signal from the test processor.

14. The apparatus of claim 8, wherein the tester comprises a first test processor for controlling a test operation of the first device, and the test head comprises a second test processor for controlling a test operation of the second device.

15. The apparatus of claim 8, wherein:
the test head includes a first set of electrical connections that directly connect the tester to the object without the use of any processing circuitry; and
the test head includes a second set of electrical connections that connect the tester to the object through processing circuitry that generates the second algorithmic pattern.

16. A method of manufacturing a semiconductor package, the method including:
stacking a first chip having a first type on a second chip having a second type different from the first type;
receiving, by the first chip, a first test pattern generated at a tester;
receiving, by the second chip, a second test pattern different from the first test pattern and generated at a test head connected to the tester; and
testing the first chip using the received first test pattern at the same time as testing the second chip using the received second test pattern.

17. The method of claim 16, further comprising:
based on the testing of the first chip and the testing of the second chip, determining that at least one of the first chip and the second chip are operating properly.

18. The method of claim 16, wherein:
the first chip is a semiconductor memory chip having a first type; and
the second chip is a semiconductor memory chip having a second type different from the first type.

19. The method of claim 16, further comprising:
stacking the first chip and the second chip on a package substrate;
receiving the first test pattern at the first chip from the package substrate; and
receiving the second test pattern at the second chip from the package substrate.

20. The method of claim 16, further comprising:
receiving the first test pattern at the first chip through a first set of electrical connections at the test head that directly connect the tester to the semiconductor package without the use of any processing circuitry; and
receiving the second test pattern at the second chip through a second set of electrical connections at the test head that connect the tester to the semiconductor package through processing circuitry that generates the second test pattern.
